(19) United States
(12) Patent Application Publication
(10) Pub. No.: US 2014/0182648 A1
(43) Pub. Date: Jul. 3, 2014

(54) ACCUMULATED TYPE THERMOELECTRIC GENERATOR FOR VEHICLE

(71) Applicant: Hyundai Motor Company, Seoul (KR)

(72) Inventors: Jong-Ho Seon, Incheon (KR); Ho-Chan An, Hwasung (KR)

(21) Appl. No.: 13/906,575

(22) Filed: May 31, 2013

(30) Foreign Application Priority Data
Dec. 27, 2012 (KR) 10-2012-0154530

(51) Int. Cl. H01L 35/30

(52) U.S. Cl. CPC H01L 35/30
USPC 136/211

(57) ABSTRACT

An accumulated type thermoelectric generator that includes an assembly of a plurality of unit modules in which a first thermoelectric element and a second thermoelectric element are installed, is mounted between an exhaust gas inlet pipe and an exhaust gas outlet pipe. A coolant inlet is formed within an upper portion of an outermost unit module in a direction of the exhaust gas outlet pipe, and a coolant outlet is formed within a lower portion of an outermost unit module in a direction of the exhaust gas inlet pipe. A pair of exhaust gas flow paths through which exhaust gas flowing into the exhaust gas inlet pipe flows may be formed on left and right sides of the unit module, and a pair of coolant flow paths through which coolant flowing into the coolant inlet flows is formed within upper and lower sides of the unit module.

### CROSS-REFERENCE TO RELATED APPLICATIONS

This application claims priority under 35 U.S.C. §119 to Korean Patent Application No. 10-2012-0154530, filed on Dec. 27, 2012, in the Korean Intellectual Property Office, the disclosure of which is incorporated herein by reference in its entirety.

### BACKGROUND OF THE INVENTION

1. Field of the Invention

The present invention relates to a thermoelectric generator, and more particularly, to an accumulated type thermoelectric generator for a vehicle.

2. Description of the Related Art

In general, a thermoelectric generator refers to an apparatus which obtains electrical energy by using a potential difference generated between a heating element and a cooling element when a temperature difference is applied to both ends of the heating element and the cooling element. Typically, the heating and cooling element are made of metals or semiconductors. As such, heat may be directly converted into electricity without mechanical operations.

Thermoelectric generator are often applied to exhaust gas equipment of industrial boilers, and power supply facilities in remote areas, and in recent years, they have begun to be applied to waste heat utilization systems for waste incinerators, geothermal power generation, ocean temperature difference power generation, or the like.

Meanwhile, since the efficiency of an engine driving alternating current generator (also called an alternator), which supplies electrical power within a vehicle to charge the battery, is only operating at about 33% efficiency, and the shaft power of the alternator should be increased as electric power consumption of the vehicle is increased, as the loss of the shaft power is increased, fuel consumption becomes increases, and an increase of pollutants are discharged due to the high fuel consumption.

The amount of energy that is required to operate the alternator changes based on a driving state of the vehicle and the amount of electrical power being consumed by the vehicle. Therefore, thermoelectric generators which collect exhaust heat from an engine have begun to be added to vehicles.

The thermoelectric generator in a vehicle typically includes a heating unit for performing heat transfer between the exhaust gas and a high temperature end of a thermoelectric module. This thermoelectric module often includes a plurality of thermoelectric semiconductors, a cooling unit for cooling a low temperature end of the thermoelectric module, and an exhaust heat recovery apparatus. The thermoelectric generator converts thermal energy, which is obtained from exhaust heat of the engine, into electric energy.

FIG. 1 is a schematic view illustrating a concept of a thermoelectric module used in a thermoelectric generator. A thermoelectric module is a circuit manufactured so that an electric current flows by thermoelectromotive force generated by connecting p-type and n-type conductors or semiconductors and setting a high temperature heat source at one side and a low temperature heat source at the other side. Typically, each thermoelectric module may output about 2 W to 4 W.

However, it is necessary to maximize a temperature difference between the heating unit and the cooling unit to increase the amount of power generated by the thermoelectric module, but because the structural efficiency of the heating unit and the cooling unit is currently poor in the thermoelectric generator for a vehicle of the related art like the one shown in FIG. 1, the temperature difference between the high temperature end and the low temperature end is smaller than what is desirable.

### SUMMARY OF THE INVENTION

The present invention has been made in an effort to provide an accumulated type thermoelectric generator for a vehicle capable of maximizing power generation efficiency of the thermoelectric generator by improving a heat exchange structure including a heating unit and a cooling unit.

An exemplary embodiment of the present invention provides an accumulated type thermoelectric generator for a vehicle in which a thermoelectric generating unit, which is an assembly of a plurality of unit modules in which a first thermoelectric element and a second thermoelectric element are installed, is mounted between an exhaust gas inlet pipe and an exhaust gas outlet pipe. A coolant inlet is formed at an upper portion of an outermost unit module in a direction of the exhaust gas outlet pipe, and a coolant inlet blocking plate is installed at a lower portion of the outermost unit module. A coolant outlet is formed at a lower portion of an outermost unit module in a direction of the exhaust gas inlet pipe, and a coolant outlet blocking plate is installed at an upper portion of the outermost unit module. A pair of exhaust gas flow paths through which exhaust gas flowing into the exhaust gas inlet pipe flows is formed at left and right sides of the unit module, and a pair of coolant flow paths through which coolant flowing into the coolant inlet flows are formed at upper and lower sides of the unit module respectively.

The accumulated type thermoelectric generator for a vehicle having the aforementioned configuration according to the exemplary embodiment of the present invention has the following advantages.

First, the thermoelectric generating unit of the thermoelectric generator according to the exemplary embodiment of the present invention has a structure in which a plurality of unit modules are accumulated, thereby improving the amount of thermoelectric power generation by efficiently configuring paths of a high temperature portion and a low temperature portion in a limited space and increasing the surface area of thermoelectric elements.

Second, because the thermoelectric generating unit of the thermoelectric generator according to the exemplary embodiment of the present invention is formed with a unit module as a base unit, the thermoelectric generating unit may appropriately cope with layout constraints of a vehicle chassis and changes in engine output by adjusting the number of unit modules used in the thermoelectric generating unit.

Third, because the unit module of the thermoelectric generating unit of the thermoelectric generator according to the exemplary embodiment of the present invention has a structure in which the unit modules are integrally assembled by a welding method without using additional sealing procedures and connecting members, assembling dispersion may be reduced and productivity may be improved.

Fourth, because the unit module of the thermoelectric generating unit of the thermoelectric generator according to the exemplary embodiment of the present invention have the same shape and the same number are repeatedly assembled, a system for supplying components is simplified and maintenance is easily performed, so that the unit module is appropriate to mass produce. Further, the structural strength of the thermoelectric generator is improved.

### BRIEF DESCRIPTION OF THE DRAWINGS

FIG. 1 is a schematic view illustrating a related thermoelectric module.

FIG. 2 is a perspective view of a thermoelectric generator according to an exemplary embodiment of the present invention.

FIG. 3 is a perspective view illustrating a state in which an exhaust gas inlet pipe and an exhaust gas outlet pipe of the thermoelectric generator according to the exemplary embodiment of the present invention are separated.

FIG. 4 is a perspective view of a unit module of the thermoelectric generator according to the exemplary embodiment of the present invention.

FIG. 5 is an exploded perspective view of a unit module of the thermoelectric generator according to the exemplary embodiment of the present invention.

FIG. 6 is a partially cut perspective view of the thermoelectric generator according to the exemplary embodiment of the present invention.

FIG. 7 is an enlarged perspective view of a partial cut portion illustrating an operation of the thermoelectric generator according to the exemplary embodiment of the present invention.

FIG. 8 is a cross-sectional view illustrating an operation of the thermoelectric generator according to the exemplary embodiment of the present invention.

FIGS. 9A-B is a cross-sectional schematic view illustrating heat exchange of the thermoelectric generator according to the exemplary embodiment of the present invention.

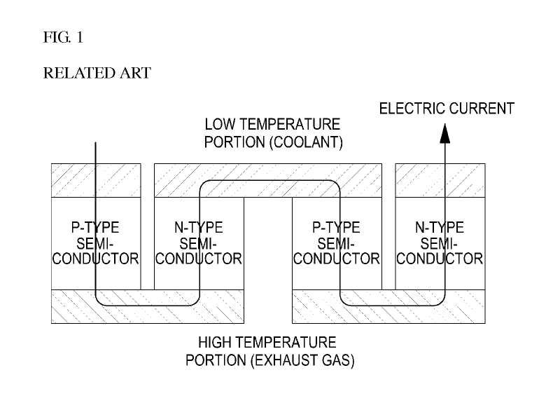

### DETAILED DESCRIPTION OF THE EMBODIMENTS

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, combustion, plug-in hybrid electric vehicles, hydrogen-powered vehicles and other alternative fuel vehicles (e.g. fuels derived from resources other than petroleum).

Additionally, it is understood that the below modules and units are embodied as hardware that is made up of structural components and should not be interpreted as software for the purposes of this application. Additionally, the terminology used herein is for the purpose of describing particular embodiments only and is not intended be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Hereinafter, a configuration of an accumulated type thermoelectric generator for a vehicle according to an exemplary embodiment of the present invention will be described in detail with reference to the drawings. However, the accompanying drawings are provided as examples in order to fully transfer the spirit of the present invention to those skilled in the art. Therefore, the present invention is not limited to the accompanying drawings and may be implemented in various forms.

Further, unless terms used in the present specification are defined, they have meanings commonly understood by those skilled in the art to which the present invention pertains and known functions and configurations which may unnecessarily obscure the gist of the present invention will not be described in detail in the following description and accompanying drawings.

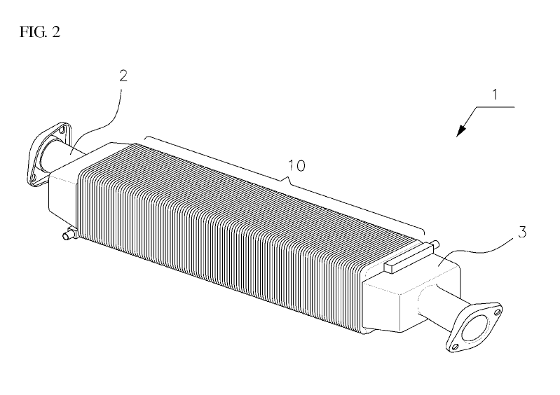

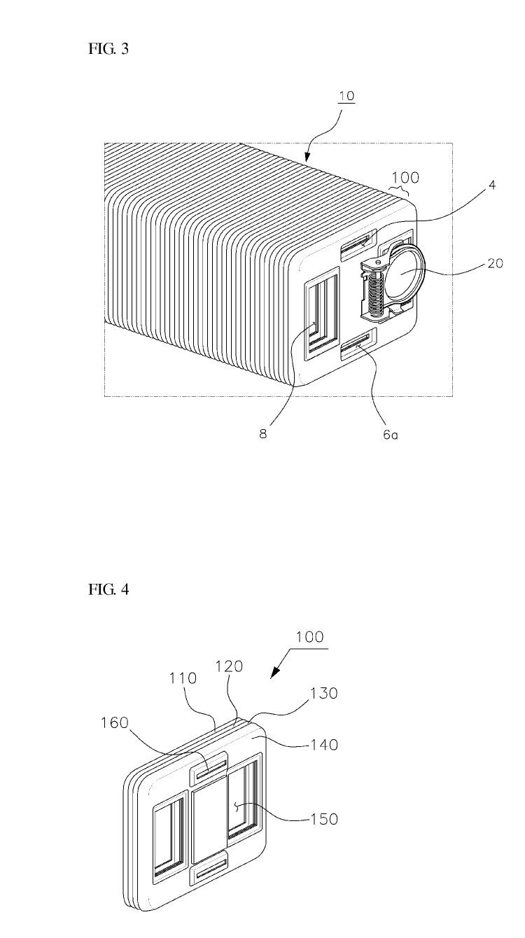

FIG. 2 is a perspective view of a thermoelectric generator according to an exemplary embodiment of the present invention, and FIG. 3 is a perspective view illustrating a state in which an exhaust gas inlet pipe and an exhaust gas outlet pipe of the thermoelectric generator according to the exemplary embodiment of the present invention are separated.

Referring to FIGS. 2 and 3, a thermoelectric generator 1 according to an exemplary embodiment of the present invention includes a thermoelectric generating unit 10 mounted between an exhaust gas inlet pipe 2 through which exhaust gas flows in and an exhaust gas outlet pipe 3 through which exhaust gas is discharged.

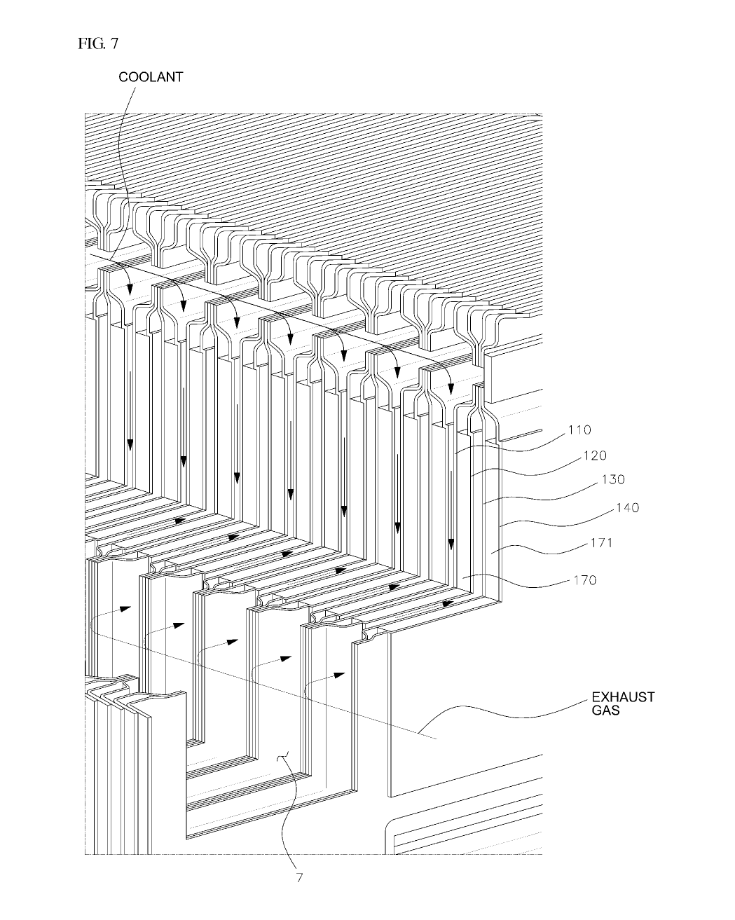

A coolant inlet 4 is formed at an upper portion of an outermost unit module 100 in a direction of the outlet pipe 3 of the thermoelectric generating unit 10 and a coolant inlet blocking plate 6a is installed at a lower portion. As illustrated in FIG. 6, a coolant outlet 5 is formed within a lower portion of an outermost unit module 100 in a direction of the inlet pipe 2 and a coolant outlet blocking plate 6b is installed within an upper portion.

Further, an exhaust gas outlet 8 may be formed on one side of the outermost unit module 100 in the direction of the outlet pipe 3 of the thermoelectric generating unit 10, and a valve 20, which controls discharge of the exhaust gas flowing into the exhaust gas inlet pipe 2, may be attached to the other side thereof.

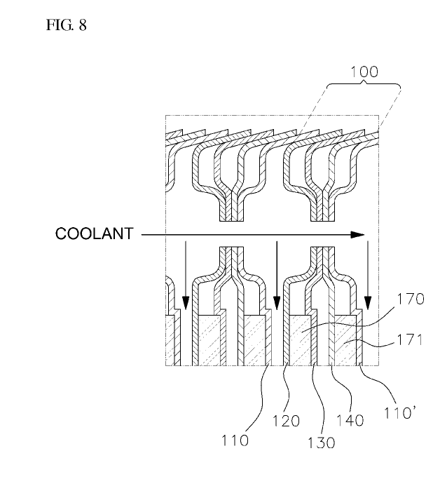

In addition, as illustrated in FIG. 7, an exhaust gas inlet 7 may be formed on one side of the outermost unit module 100 in the direction of the inlet pipe 2, and an exhaust gas blocking plate 9 may be installed at the other side thereof.

In the thermoelectric generating unit 10 according to the exemplary embodiment of the present invention, heat transfer occurs between the heat from engine exhaust gas and cold coolant via a process in which the exhaust gas flowing into the exhaust gas inlet pipe 2 is discharged to the outside through the exhaust gas outlet pipe 3, and the coolant flows from the coolant inlet 4 to the coolant outlet 5.

Further, via heat transfer, a temperature difference is applied to both ends of a first thermoelectric element 170 and a second thermoelectric element 171 which may be made of metal or semiconductor installed in the thermoelectric generating unit 10, and thereby electric energy is generated by a potential difference generated between a heated thermoelectric element and a cooled thermoelectric element.

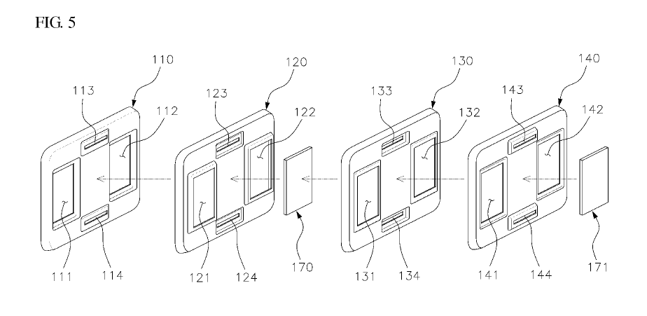

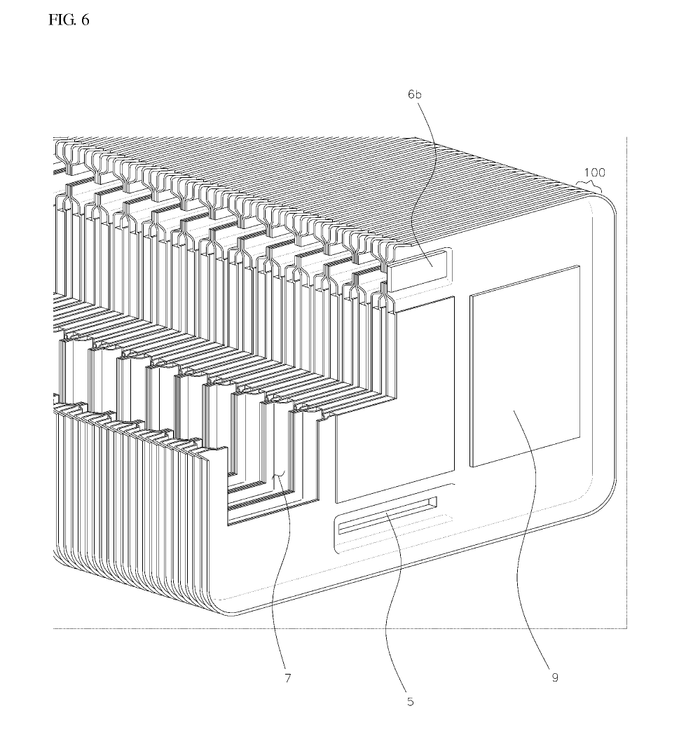

The thermoelectric generating unit 10 according to the exemplary embodiment of the present invention is an assembly of a plurality of unit modules 100 in which the first thermoelectric element 170 and the second thermoelectric element 171 are installed, FIG. 4 is a perspective view illustrating a configuration of the unit module 100, and FIG. 5 is an exploded perspective view of the unit module 100.

Referring to FIGS. 4 and 5, the unit module 100 is the unit module 100 formed by sequentially coupling a first plate 110, a second plate 120, a third plate 130, and a fourth plate 140 to each other in a manner such that the second plate 120 is attached to a front surface of the first plate 110, the third plate 130 is attached to a front surface of the second plate 120, and the fourth plate 140 is attached to a front surface of the third plate 130.

The unit module 100 includes a pair of exhaust gas flow paths 150 through which the exhaust gas flows formed on left and right sides of the module, and includes a pair of coolant flow paths 160 through which the coolant flows that are formed on upper and lower sides of the module between the exhaust gas flow paths 150.

More specifically, a pair of first plate exhaust gas through apertures 111 and 112 through which the exhaust gas flows on the left and right sides and a pair of first plate coolant through apertures 113 and 114 through which the coolant flows on the upper and lower sides are formed within the first plate 110 of the unit module 100. Likewise, a pair of second plate exhaust gas through apertures 121 and 122 through which the exhaust gas flows on the left and right sides and a pair of second plate coolant through apertures 123 and 124 through which the coolant flows on the upper and lower sides are formed at the second plate 120 of the unit module 100.

In addition, a pair of third plate exhaust gas through apertures 131 and 132 through which the exhaust gas flows on the left and right sides and a pair of third plate coolant through apertures 133 and 134 through which the coolant flows on the upper and lower sides are formed at the third plate 130 of the unit module 100. Finally in the exemplary embodiment of the present invention, a pair of fourth plate exhaust gas through apertures 141 and 142 through which the exhaust gas flows at the left and right sides and a pair of fourth plate coolant through apertures 143 and 144 through which the coolant flows on the upper and lower sides are formed at the fourth plate 140 of the unit module 100.

The first plate 110 and the second plate 120 may be attached to each other by a welding method without using additional sealing and connecting members. The attachment by the welding method may be identically applied to the attachment between the second plate 120 and the third plate 130 and the attachment between the third plate 130 and the fourth plate 140, respectively. Further, the first thermoelectric element 170 made of a metal or semiconductor may be attached between the second plate 120 and the third plate 130.

In addition, the second thermoelectric element 171 made of metal or semiconductor may be attached to a surface of the fourth plate 140, and the second thermoelectric element 171 attached to the surface of the fourth plate 140 comes into contact with a back surface of a first plate 110 of another unit module 100 which is coupled to the front surface of the fourth plate 140.

Therefore, in the unit module 100 according to the exemplary embodiment of the present invention configured as described above, when the first plate 110, the second plate 120, the third plate 130, and the fourth plate 140 are coupled, the pair of exhaust gas flow paths 150 of the unit module 100 is formed by overlapping the exhaust gas through apertures 111, 112, 121, 122, 131, 132, 141, and 142 of the first plate 110, the second plate 120, the third plate 130, and the fourth plate 140 with each other respectively, and the pair of coolant flow paths 160 of the unit module 100 is formed by overlapping the coolant through apertures 113, 114, 123, 124, 133, 134, 143, and 144 of the first plate 110, the second plate 120, the third plate 130, and the fourth plate 140 with each other, respectively.

In the unit module 100 according to the exemplary embodiment of the present invention configured as described above, as illustrated in FIG. 6, which is a partially cut perspective view of the thermoelectric generator according to the exemplary embodiment of the present invention, and FIG. 7, which is an enlarged perspective view of a partial cut portion illustrating an operation of the thermoelectric generator according to the exemplary embodiment of the present invention, because the exhaust gas through aperture at one side of the outermost unit module 100 in the direction of the inlet pipe 2 is closed by the exhaust gas blocking plate 9, the exhaust gas flowing from the exhaust gas inlet pipe 2 flows into the exhaust gas inlet 7 on the other side of the outermost unit module 100 in the direction of the inlet pipe 2 and flows to the exhaust gas outlet pipe 3 through the exhaust gas flow path 150 of each unit module 100.

In addition, because the coolant through aperture formed at a lower portion of the outermost unit module 100 in the direction of the outlet pipe 3 is closed by the coolant inlet blocking plate 6a, the coolant flows into the coolant inlet 4 formed at an upper portion of the outermost unit module 100 in the direction of the outlet pipe 3, and flows to the coolant outlet 5 through the coolant flow path 160 of each unit module 100. Here, because the coolant through aperture formed at the upper portion of the outermost unit module 100 in the direction of the inlet pipe 2 is closed by the coolant outlet blocking plate 6b, the coolant is discharged only to the coolant outlet 5 formed at the lower portion of the outermost unit module 100 in the direction of the inlet pipe 2.

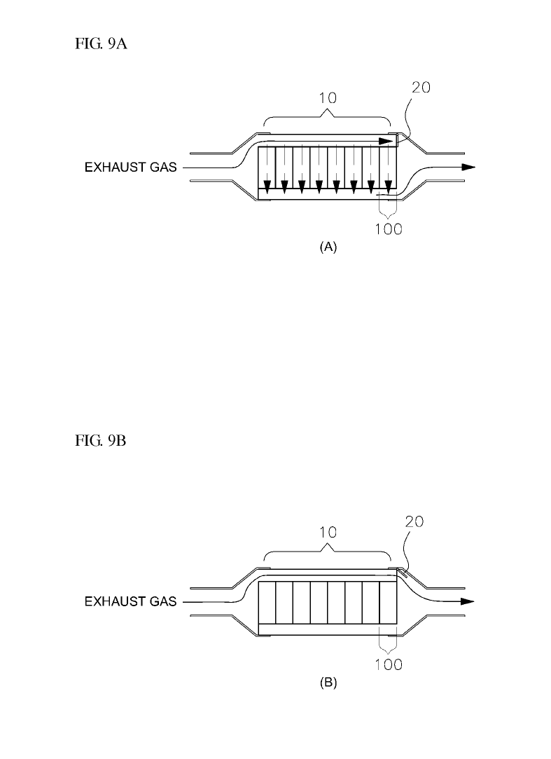

Therefore, as illustrated in a cross-sectional view of the unit module 100 of FIG. 8, because the coolant flowing into the coolant inlet 4 flows in between the first plate 110 and the second plate 120 of each unit module 100 through the coolant flow path 160 of the unit module 100. The exhaust gas flowing into the exhaust gas inlet 7 flows in between the third plate 130 and the fourth plate 140 of the unit module 100. The coolant, which flows in a vertical direction through the coolant flow path 160, and the exhaust gas, which flows into the exhaust gas inlet 7, flows in a horizontal direction are perpendicular to each other, and thus the heat transfer between the coolant and the exhaust gas is efficiently performed. By the efficient heat transfer between the exhaust gas and the coolant, a larger temperature difference is applied to both ends of the first thermoelectric element 170, which is attached between the second plate 120 and the third plate 130, and a larger temperature difference is applied to both ends of the second thermoelectric element 171, which is attached between the fourth plate 130 and the first plate 110′ of another unit module 100. Therefore, since a larger potential difference is generated between the heated thermoelectric element and the cooled thermoelectric element, the generation of the electric energy may be efficiently performed.

Meanwhile, according to the exemplary embodiment of the present invention, in the thermoelectric generating unit 10 according to the exemplary embodiment of the present invention, the valve 20 may be attached to the other side of the unit module 100 positioned outermost in a direction of the exhaust gas outlet pipe 3. As illustrated in FIG. 9A, in the valve 20, the thermoelectric generation is performed by the aforementioned heat transfer between the coolant and the exhaust when the valve 20 is closed, in which case the exhaust gas flowing into the exhaust gas inlet pipe 2 is not discharged by the valve 20 but instead is discharged only through the exhaust gas outlet 8.

However, as illustrated in FIG. 9B, when the valve 20 is opened, since the exhaust gas flowing into the exhaust gas inlet pipe 2 passes through the valve 20 in an opened state, and is discharged through the exhaust gas outlet 8, a bypass operation is performed in which the thermoelectric generation of the thermoelectric generating unit 10 is partially limited. The bypass operation limits the thermoelectric generation to prevent overheating of the thermoelectric element due to high load driving.

The present invention is described with reference to the embodiments illustrated in the drawings, which are only example and can be implemented by various embodiments. Therefore, the true scope of the present invention will be defined only by claims.

What is claimed is:

1. An accumulated type thermoelectric generator for a vehicle, comprising:
a thermoelectric generating unit including an assembly of a plurality of unit modules which are mounted between an exhaust gas inlet pipe and an exhaust gas outlet pipe, wherein in the thermoelectric generating unit,
a coolant inlet is formed within an outermost unit module in a direction of the exhaust gas outlet pipe, a coolant outlet is formed within a lower portion of an outermost unit module in a direction of the exhaust gas inlet pipe, and
a first thermoelectric element and a second thermoelectric element, which generate a potential difference in accordance with heat transfer between exhaust gas and coolant while exhaust gas is flowing into the exhaust gas inlet pipe and the coolant is flowing into the coolant inlet flow in directions perpendicular to each other, are installed in the thermoelectric generating unit.

2. The accumulated type thermoelectric generator of claim 1, wherein
a pair of exhaust gas flow paths through which the exhaust gas flowing into the exhaust gas inlet pipe flows is formed on left and right sides of the unit module, and
a pair of coolant flow paths through which the coolant flowing into the coolant inlet flows is formed on upper and lower sides of the unit module.

3. The accumulated type thermoelectric generator of claim 2, wherein
a coolant inlet blocking plate is disposed within the outermost unit module in the direction of the exhaust gas outlet pipe, and
a coolant outlet blocking plate is disposed within the outermost unit module in the direction of the exhaust gas inlet pipe.

4. The accumulated type thermoelectric generator of claim 2, wherein
an exhaust gas outlet is formed on one side of the outermost unit module in the direction of the outlet pipe of the thermoelectric generating unit and a valve is connected to the other side of the outermost unit module, and
an exhaust gas inlet is formed on one side of the outermost unit module in the direction of the inlet pipe and an exhaust gas blocking plate is disposed on the other side of the outermost unit module.

5. The accumulated type thermoelectric generator of claim 2, wherein
the unit module is formed by sequentially coupling a first plate, a second plate, a third plate, and a fourth plate to each other,
a pair of first plate exhaust gas through apertures through which the exhaust gas flows are formed on left and right sides of the first plate, and a pair of first plate coolant through apertures through which the coolant flows are formed on upper and lower sides of the first plate,
a pair of second plate exhaust gas through apertures through which the exhaust gas flows are formed at left and right sides of the second plate, and a pair of second plate coolant through apertures through which the coolant flows are formed on upper and lower sides of the second plate,
a pair of third plate exhaust gas through apertures through which the exhaust gas flows are formed at left and right sides of the third plate, and a pair of third plate coolant through apertures through which the coolant flows are formed on upper and lower sides of the third plate, and
a pair of fourth plate exhaust gas through apertures through which the exhaust gas flows are formed on left and right sides of the fourth plate, and a pair of fourth plate coolant through apertures through which the coolant flows are formed on upper and lower sides of the fourth plate.

6. The accumulated type thermoelectric generator of claim 5, wherein
the first thermoelectric element is attached between the second plate and the third plate, and
the second thermoelectric element is attached to a surface of the fourth plate.

7. The accumulated type thermoelectric generator of claim 5, wherein the first plate, the second plate, the third plate, and the fourth plate of the unit module are attached by a welding method.

8. A thermoelectric generator system installed in an exhaust line of a vehicle, comprising:
an exhaust pipe inlet;
an exhaust pipe outlet and
a thermal electric generator including a plurality of unit modules which are mounted between the exhaust gas pipe inlet and the exhaust gas pipe outlet, wherein a coolant inlet is formed within an outermost unit module in a direction of the exhaust gas outlet pipe, a coolant outlet is formed within a lower portion of an outermost unit module in a direction of the exhaust gas inlet pipe, and a first thermoelectric element and a second thermoelectric element are installed in the thermoelectric generator,
wherein coolant flow and exhaust flow within the thermoelectric generator are perpendicular to each other.

9. The thermoelectric generator system of claim 8, wherein
a pair of exhaust gas flow paths through which the exhaust gas flowing into the exhaust gas inlet pipe flows is formed on left and right sides of the unit module, and
a pair of coolant flow paths through which the coolant flowing into the coolant inlet flows is formed on upper and lower sides of the unit module.

10. The thermoelectric generator system of claim 9, wherein
a coolant inlet blocking plate is disposed within an outermost unit module in a direction of the exhaust gas outlet pipe, and
a coolant outlet blocking plate is disposed within the outermost unit module in the direction of the exhaust gas inlet pipe.

11. The accumulated type thermoelectric generator of claim 9, wherein
an exhaust gas outlet is formed on one side of the outermost unit module in the direction of the outlet pipe of the thermoelectric generating unit and a valve is connected to the other side of the outermost unit module, and
an exhaust gas inlet is formed on one side of the outermost unit module in the direction of the inlet pipe and an exhaust gas blocking plate is disposed on the other side of the outermost unit module.

12. The accumulated type thermoelectric generator of claim 9, wherein
the unit module is formed by sequentially coupling a first plate, a second plate, a third plate, and a fourth plate to each other,
a pair of first plate exhaust gas through apertures through which the exhaust gas flows are formed on left and right sides of the first plate, and a pair of first plate coolant through apertures through which the coolant flows are formed on upper and lower sides of the first plate,
a pair of second plate exhaust gas through apertures through which the exhaust gas flows are formed at left and right sides of the second plate, and a pair of second plate coolant through apertures through which the coolant flows are formed on upper and lower sides of the second plate,
a pair of third plate exhaust gas through apertures through which the exhaust gas flows are formed at left and right sides of the third plate, and a pair of third plate coolant through apertures through which the coolant flows are formed on upper and lower sides of the third plate, and
a pair of fourth plate exhaust gas through apertures through which the exhaust gas flows are formed on left and right sides of the fourth plate, and a pair of fourth plate coolant through apertures through which the coolant flows are formed on upper and lower sides of the fourth plate.

13. The accumulated type thermoelectric generator of claim 2, wherein
the first thermoelectric element is attached between the second plate and the third plate, and
the second thermoelectric element is attached to a surface of the fourth plate.

14. The accumulated type thermoelectric generator of claim 12, wherein the first plate, the second plate, the third plate, and the fourth plate of the unit module are attached by a welding method.
